(19) United States
(12) Patent Application Publication
(10) Pub. No.: US 2008/0049394 A1
(43) Pub. Date: Feb. 28, 2008

(54) Method, apparatus and computer system for air mover configuration

(75) Inventor: Yoshifumi Nishi, Ushiku (JP)

Correspondence Address: INTEL CORPORATION;c/o INTELLEVATE, LLC, P.O. BOX 52050, MINNEAPOLIS, MN, 55402, US

(73) Assignee: INTEL CORPORATION

(21) Appl. No.: 11/509,110

(22) Filed: Aug. 23, 2006

(51) Int. Cl. G05D 23/00; H05K 7/20

(52) U.S. Cl. 361/695; 165/299

(57) ABSTRACT

Some embodiments of a method, apparatus and computer system are described for configuring one or more air movers. A computer system may include a housing and an air mover coupled to an electronic device and positioned in relative proximity to an electronic component. In some embodiments, the air mover has an intake region, and is configured such that the intake region may include a first bisection larger than a second bisection. In some embodiments, a configuration module may be coupled to the air mover, such that the configuration module may alter the configuration of the air mover such that the intake region is altered. Other embodiments are described.

### BACKGROUND

1. Technical Field

Some embodiments of the invention generally relate to placement and alignment of an air mover.

2. Discussion

In recent years, electronic components and systems have been made to meet increasing demands for better performance. These demands have led to a decrease in the weight and an increase in the density of components. These factors lead to increases in heat generation. Particularly in mobile, portable, and handheld computing environments, but also in desktop and server computing environments, these factors can lead to overheating, which may negatively affect performance, and can significantly reduce battery life.

The above-mentioned factors increase the need for effective cooling of electronic components. In particular, there is a need for cooling systems that, at least, are more efficient at transferring heat from electronic components within electronic devices.

### BRIEF DESCRIPTION OF THE DRAWINGS

Various advantages of embodiments of the present invention will become apparent to one of ordinary skill in the art by reading the following specification and appended claims, and by referencing the following drawings, in which:

FIG. 1 illustrates an example of an air mover in a computer system according to some embodiments of the invention;

FIG. 2 illustrates an example of an air mover with a substantially uniform intake region according to some embodiments of the invention;

FIG. 3 illustrates an example of an air mover with a substantially non-uniform intake region according to some embodiments of the invention;

FIG. 4 illustrates examples of flow dependence on intake region according to some embodiments of the invention;

FIG. 5 illustrates examples of intake regions according to some embodiments of the invention;

FIG. 6 illustrates examples comparing flow based on intake region configurations according to some embodiments of the invention;

FIG. 7 illustrates examples comparing pressure-flow (P-Q) curves according to some embodiments of the invention;

FIG. 8 illustrates an example air mover apparatus according to some embodiments of the invention; and

FIG. 9 illustrates a flowchart for configuring an air mover according to some embodiments of the invention.

### DETAILED DESCRIPTION

Reference is made to some embodiments of the invention, examples of which are illustrated in the accompanying drawings. While the invention will be described in conjunction with the embodiments, it will be understood that they are not intended to limit the invention to these embodiments. On the contrary, the invention is intended to cover alternatives, modifications and equivalents, which may be included within the spirit and scope of the invention as defined by the appended claims. Moreover, in the following detailed description of the invention, numerous specific details are set forth in order to provide a thorough understanding of the invention. However, the invention may be practiced without these specific details. -In other instances, well-known methods, procedures, components and circuits have not been described in detail as not to unnecessarily obscure aspects of the invention.

Some embodiments of the invention are directed to a method, apparatus and computer system for configuring an air mover. In some embodiments of the invention, the computer system may include computing devices and electronic appliances, including, but not limited to, mobile computers, notebooks, laptops, personal digital assistants (PDAs), desktop computers, servers, such as blade or rack mounted servers, cellular telephones, personal electronic devices, and the like. Moreover, in some embodiments, the air mover is a blower fan, an axial fan, a coaxial fan, a piezoelectric fan, and/or a membrane fan.

Indeed, reference in the specification to an embodiment or some embodiments of the invention means that a particular feature, structure or characteristic described in connection with the embodiment is included in at least one embodiment of the invention. Thus, the appearances of the phrase “in one embodiment” or “in some embodiments” appearing in various places throughout the specification are not necessarily all referring to the same embodiment, and are not meant to require the presence of other embodiments, which may be used exclusively, inclusively, or alternatively, as one of ordinary skill in the relevant art would appreciate based at least on the teachings provided herein.

Furthermore, while air and air movers are described with respect to the embodiments of the invention, one of ordinary skill in the relevant art would appreciate the application of the embodiments to other fluid mediums besides air, such as, but not limited to other gases, gaseous mixtures, liquids and other mediums which exhibit flow. In some embodiments, a medium or mediums other than air may be used, and certain implementation details may be altered as needed to accommodate the differences in density and flow rate of the medium as compared to air. Thus, while air and air movers are specifically discussed, they are not meant to preclude the application of embodiments of the invention with mediums other than air.

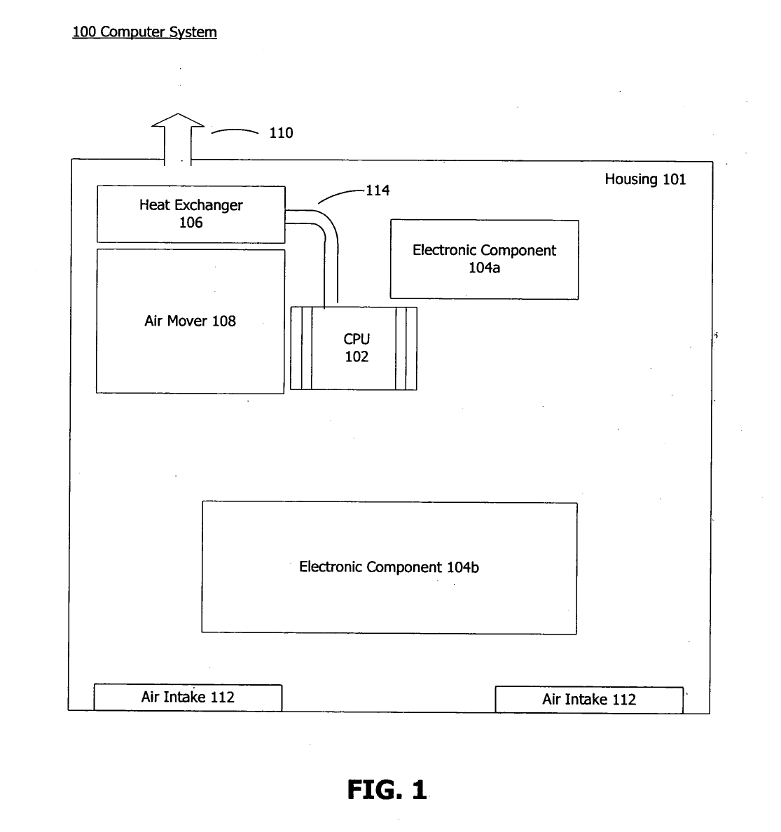

FIG. 1 illustrates an example of an air mover in a computer system according to some embodiments of the invention. A computer system 100 may include a housing 101, a central processing unit (CPU) 102, and one or more electronic components 104. The CPU 102 may be in direct or thermal contact with a heat exchanger 106 which may be in proximity to an air mover 108. In some embodiments, the heat exchanger 106 may be coupled to the CPO 102 by a heat pipe 114 or other conduit.

The air mover 108 may force air out of the computer system 100 by passing near, over, or through the heat exchanger 106. The air mover 108 may serve to establish or provide a direction for air flow, shown at 110, where external air comes into the system at one or more of the air intakes 112, according to some embodiments of the invention.

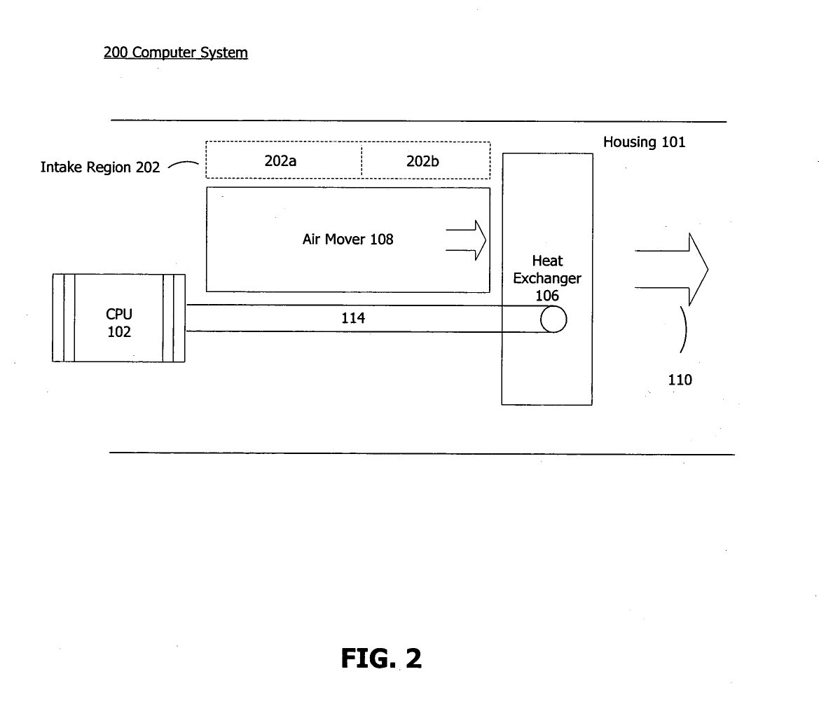

FIG. 2 illustrates an example of the air mover 108 with a substantially uniform intake region 202 according to some embodiments of the invention. In some embodiments of the invention, a computer system 200 may include a housing 101, a central processing unit (CPU) 102, and a heat exchanger 106 and an air mover 108. The CPU 102 may be in direct or thermal contact with the heat exchanger 106 which may further be in proximity to the air mover 108. In some embodiments, the heat exchanger 106 may be coupled to the CPO 102 by a heat pipe 114 or other conduit. The air mover 108 may force air out of the computer system 200. The air mover 108 may serve to establish a direction for air flow, shown at 110.

Furthermore, in some embodiments, the intake region 202 may be formed from the relative positions of the air mover 108 within the house 101. In some embodiments, the intake region 202 may be bisected into two regions—202a and 202b. In FIG. 2, these regions may be substantially uniform and provide about the same volume of air to the air mover 108, as one of ordinary skill in the relevant art would appreciated based at least on the teachings provided herein.

The term ‘bisect’ and ‘bisection’ are used to describe two distinct areas or volumes of the intake region. As one of ordinary skill in the relevant art would appreciate, the two bisected regions are constrained by the bounds of the intake region, as a whole. Description of one region with respect to another is mean to aid the discussion of the method and apparatus for altering the intake region such that one bisected region encompasses a greater area or volume than the other bisected region.

Furthermore, based on the teachings described herein, one of ordinary skill in the relevant art would appreciate that the CPU 102 and air mover 108 may operate without the heat exchanger 106. Moreover, one of ordinary skill in the relevant art would appreciate that the shapes, sizes, and/or positions of the various components may be altered and are described in relative terms. As such, in some embodiments, the constraining nature of the housing 101 may serve to increase the benefit of tilting the air mover 108, as is described in additional detailed elsewhere herein.

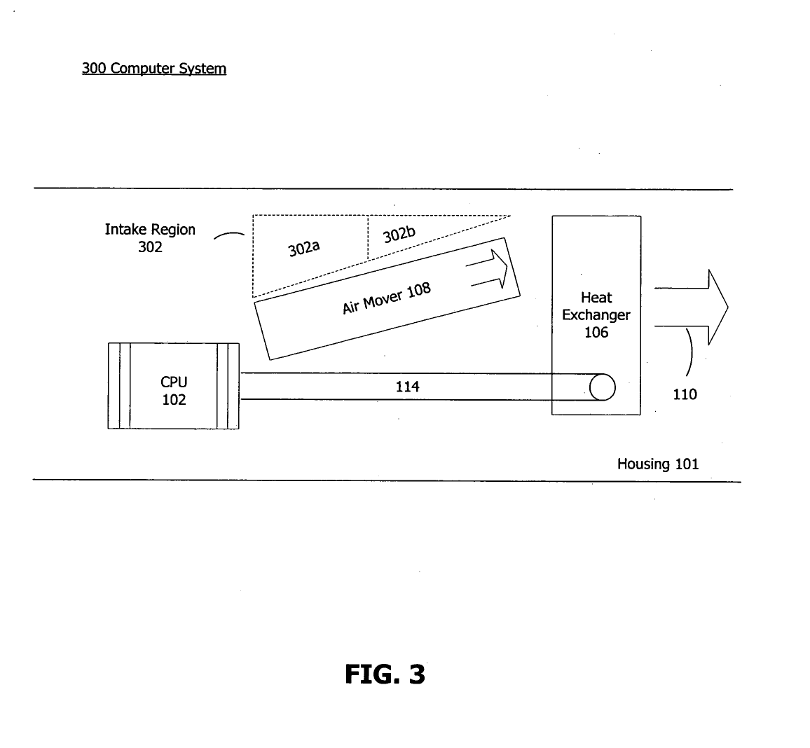

FIG. 3 illustrates an example of the air mover 108 with a substantially non-uniform intake region 302 according to some embodiments of the invention. Similar to system 200, computer system 300 illustrates an embodiment where the air mover 108 may be configured at an angle with respect to the housing 101 and heat exchanger 106. As a result, the intake region may also be altered, as shown by intake region 302, such that the region has substantially non-uniform bisected regions 302a and 302b.

According to some embodiments, as described in detail elsewhere herein, the substantially non-uniform intake region provides advantages for the cooling of the computer system. In some embodiments, the angle or tilt of the air mover 108 may be only about a single or a few degrees; or the angle may be approaching 90 degrees relative to the surface of the housing 101 or heat exchanger 106. As one of ordinary skill in the relevant art would appreciate, based at least on the teachings provided herein, the angle of the air mover may depend on the direction of output. As shown in FIG. 3, the air mover's direction of output may not be aligned with that of the other components, yet it may still provide an improvement in performance.

Furthermore, in some embodiments, an electronic component 104 may be used instead of or along with CPU 102. In some embodiments, the electronic component 104 may be one of a central processing unit, a processor, a memory, a hard drive, a network card, a video graphics card, a motherboard, and/or a heat source. In some embodiments, the computer system may be an electronic device such as a mobile computer, personal computer, and/or server, such as, but not limited to blade or rank-mounted servers.

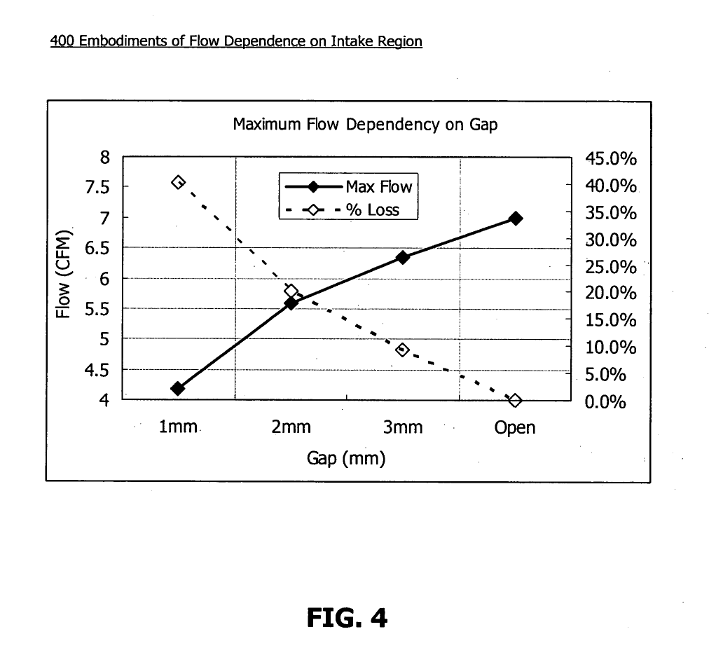

In addition, with respect to FIG. 3, in some embodiments of the invention, the air mover 108, may be used in combination with or integrated with the heat exchanger 106. The heat exchanger 106 may include a heat spreader or a heat sink, with or without various arrangements of fins, blocks, or other surface features to increase the surface area of the exchanger 106 and thus further increase the transfer of heat, according to some embodiments. The various designs of exchangers, spreader, and sinks are well-known in the art and one of ordinary skill in the relevant art would appreciate, based at least on the teachings described herein, especially with respect to FIGS. 4-9, how to position the air mover 108 with respect to the other components of the computer system 300 to provide for or maximize the enhancement of heat transfer.

In alternative embodiments of the invention, as one of ordinary skill in the relevant art would appreciate, based at least on the teachings described herein, that the embodiments of the invention may not require but may utilize more than one air mover 108. Furthermore, that one of ordinary skill would appreciate that the heat exchanger 106 may be replaced with alternative heat transfer components, as are well-known in the art and described with some alternatives elsewhere herein.

FIG. 4 illustrates examples of flow dependence on intake region according to some embodiments of the invention. As described elsewhere herein, some embodiments of the invention describe placement and configuration of an air mover in a housing, such as, but not limited to, a space-constrained device. In some embodiments, the air mover 108 may be placed parallel to the top and/or bottom surfaces of the housing 101 to allow for substantially uniform open area (intake region) for the top and/or bottom inlets (air intakes of the air mover). In some embodiments, the air mover 108 is positioned and/or configured at an angle that may widen the intake region on one side at the expense of the other side.

In some embodiments, measurements may be taken to arrive at examples similar to FIG. 4, where the amount of gap between the air mover and the housing may be one of the largest contributing factors in performance degradation of the air mover while in the system. As such, the examples of FIG. 4 illustrated, according to some embodiments, the dependency of maximum flow on the size of the gap between the air mover and the housing, or, in some embodiments, the width of the intake region, such as uniform region 202.

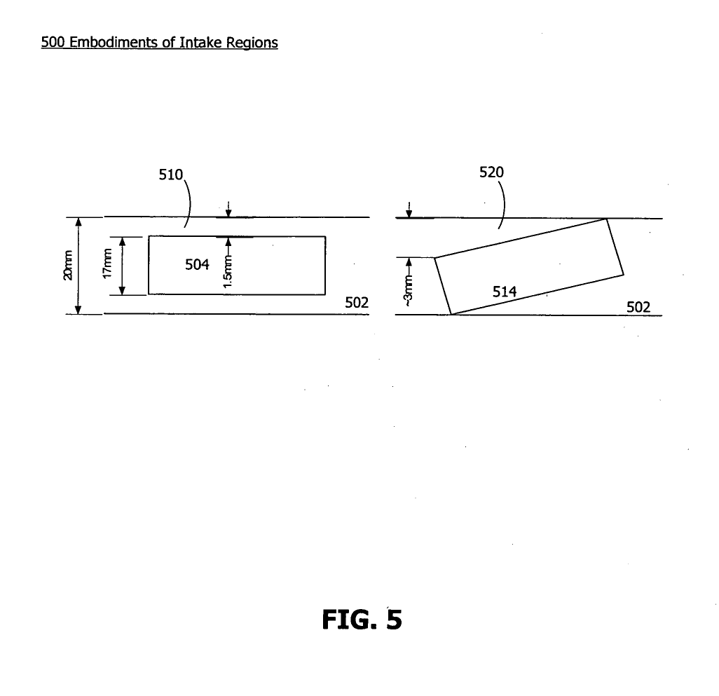

FIG. 5 illustrates examples of intake regions according to some embodiments of the invention. As described elsewhere herein, by tilting or angling the air mover, in some embodiments, the gap on one side of the air mover is increased compared to the other side. In other words, and with respect to embodiments 500, an intake region 510 of an air mover 504 may be 1.5 mm wide, that is, the distance between the air mover 504 and the housing 502.

In some embodiments, the air mover may be configured as air mover 514, at an angle that increased the width of intake region 520 at one side to about 3 mm wide. As one of ordinary skill in the relevant art would appreciate, based at least on the teachings provided herein, the actual widths and measurements are not a restriction on the embodiments of the invention and are merely for illustration.

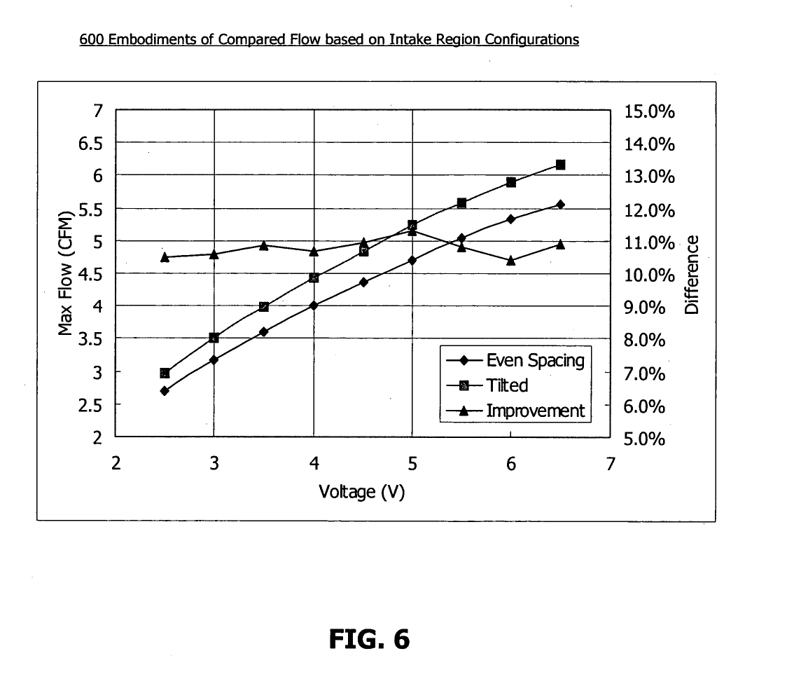

FIG. 6 illustrates examples comparing flow based on intake region configurations according to some embodiments of the invention. As described elsewhere herein, in some embodiments, the altering of the position and/or configuration of the air mover may provide an overall improvement in the performance of the air mover. In some embodiments, the increased width of one bisected region may provided a greater improvement than any reduced performance in the other bisected region due to decreased width of that region. As illustrated in embodiments 600, tilting the air mover may provide a measurable improvement in the maximum flow of the air mover over an air mover in a configuration with a substantially uniform intake region.

As one of ordinary skill in the relevant art would appreciate, based at least on the teachings described herein, the term ‘flow’ may also mean ‘flow capacity’, ‘discharge capacity’ and/or ‘intake capacity’, and may be represented by the letter Q. Flow is typically described in terms of cubic feet per minute (CFM) or ft³/min. Moreover, as one of ordinary skill in the relevant art would appreciate, based at least on the teachings described herein, flow may be proportional to an area of intake or discharge and a flow velocity. While the term ‘flow’ is used throughout the description of these embodiments, one or more of the other terms may be used and are not be meant to infer a different quality.

Similarly, the term ‘pressure’ may be used to describe the force exerted in all directions, measured perpendicular to the flow of the medium, and may be created by the air mover. Pressure may be represented by the letter P and is typically quantitatively described as a number of inches (in.) of water (H₂O).

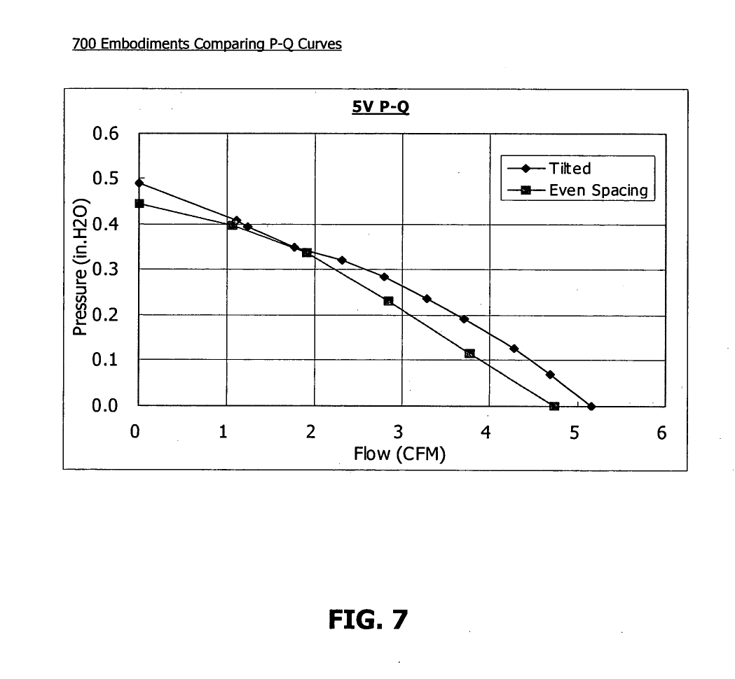

FIG. 7 illustrates examples comparing pressure-flow (P-Q) curves according to some embodiments of the invention. As illustrated, a tilted air mover may obtain a greater flow for a given pressure, when compared to a substantially uniform (or substantially evenly spaced) air mover, as described in some embodiments.

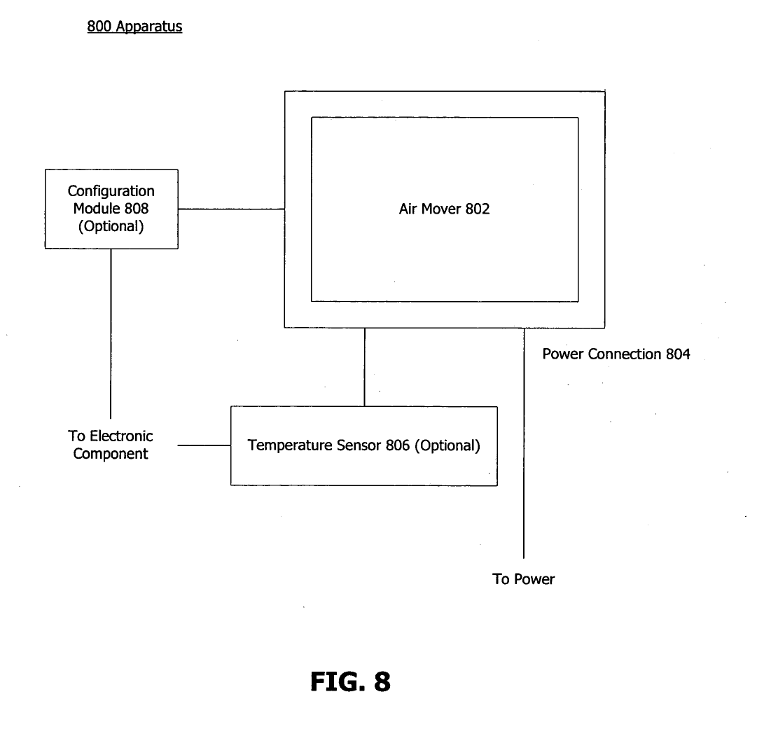

FIG. 8 illustrates an example air mover apparatus 800 according to some embodiments of the invention. The apparatus 800 may include an air mover 802 with a power connection 804, in some embodiments, which in some embodiments of the invention may include a blower-type fan, an axial fan, a coaxial fan, a piezoelectric fan, and/or a membrane fan. In some embodiments of the invention, the air mover 302 may be coupled, either directly or indirectly, to a power source by power connection 304. The power source may be from the computer system or one of its components.

In some embodiments, a temperature sensor 806 may be optionally coupled to the air mover 802. The temperature sensor 806 may be further coupled to an electronic component, such as, but not limited to the electronic component 104. In operation, in some embodiments, the temperature sensor 806 may determine a temperature of the electronic component and notify or activate the air mover 802, which may be off, or in a low or high mode of operation, depending on the amount of enhancement (cooling) required. In other embodiments, the temperature sensor may determine the temperature of the chassis skin in the vicinity of the electronic component if its temperature is likely to exceed acceptable limits.

In some embodiments, a configuration module 808 may be optionally coupled to the air mover 802. The configuration module 808 may be further coupled to the electronic component, such as, but not limited to the electronic component 104. In operation, in some embodiments, the configuration module 808 may alter the configuration of the air mover 802 such that the intake region is altered. In some embodiments, the configuration module 808 may determine the appropriate configuration based on temperature information. According to some embodiments, the air mover 802 may include one or more levers, actuators, motors, or guides to alter the tilt, angle, or position of the air mover 802, as one of ordinary skill in the relevant art would appreciate based at least on the teachings described herein.

In some embodiments, the electronic component may include a spreader or heat exchanger. Furthermore, in some embodiments, the air mover may be integrated into the spreader or the heat exchanger, and/or the air mover (without or without the spreader or the heat exchanger) may be coupled to the electronic component.

As one of ordinary skill would appreciate based at least on the teachings provided herein, the electronic component may be a memory, a hard drive, a network card, a video graphics card, a motherboard, or a heat source. Moreover, in some embodiments, the apparatus and the electronic component may be implemented within an electronic device, which may include a computer system, computing device, or electronic appliance.

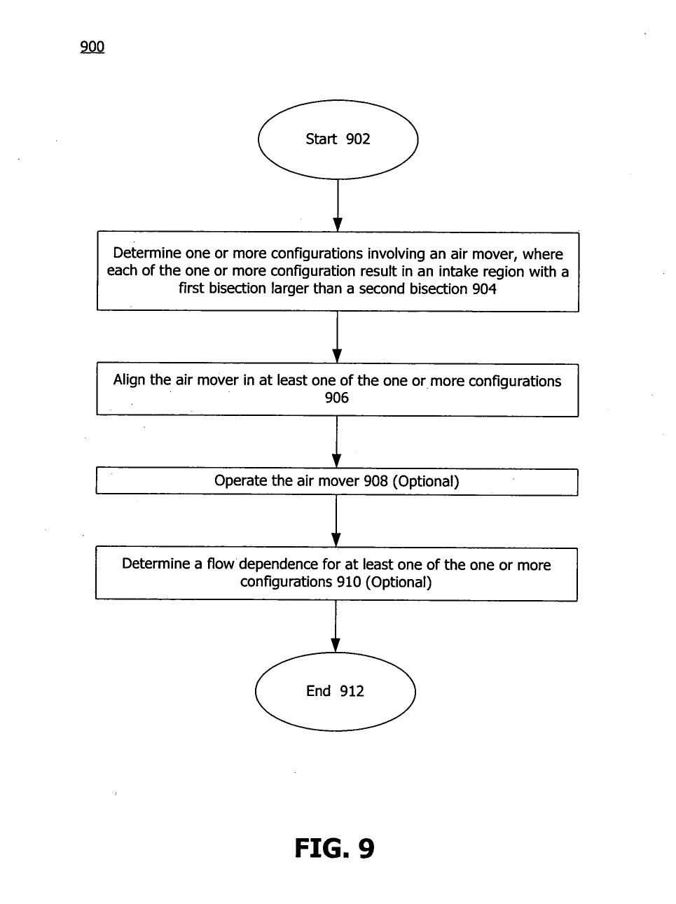

FIG. 9 illustrates a flowchart 900 for configuring an air mover according to some embodiments of the invention. The method starts at 902 and may then proceed to element 904, where it may determine one or more configurations involving the air mover. In some embodiments, the one or more configurations may result in an intake region with a first bisection larger than a second bisection. In some embodiments, a configuration module, such as, but not limited to configuration module 808, may make this determination. In some embodiments, the determination may be made during assembly of the system and the configuration of the air mover set prior to operation of the apparatus or system. The method may then proceed to 906.

At 906, the method may align the air mover in at least one of the one or more configurations. In some embodiments, the configuration module may facilitate this alignment. In some embodiments, the air mover may be able to align itself. In some embodiment, the air mover may be aligned during assembly of the apparatus or system. The method may then proceed to 908.

At 908, the method may optionally operate the air mover. In some embodiments the air mover may be the air mover 108 or 808, and, as one of ordinary skill in the relevant art would appreciate based at least on the teachings provided herein, the operation of the air mover with a non-uniform intake region may improve the operation of the air mover. In some embodiments, the air mover may operate to move air directly over an electronic component rather than onto a heat exchanger. Moreover, in some embodiments, the electronic component may be a central processing unit, a processor, a memory, a hard drive, a network card, a video graphics card, a motherboard, or a heat source. The method may then proceed to 910.

At 910, the method may optionally determine the flow dependence for at least one of the one or more configurations. In some embodiments, the flow dependence information may be used to further improve the performance of the configured air mover. In some embodiments, the flow dependence information may be use in the one or more configurations of element 904. The method may then proceed to 912.

At 912, the method may terminate and may repeat any or all of the elements 902-910, as one of ordinary skill in the relevant art would appreciate, based at least on the teachings provided herein. According to some embodiments of the invention, one or more of the elements 904, 906, 908, and/or 910 may occur independently.

Embodiments of the present invention may be described in sufficient detail to enable those skilled in the art to practice the invention. Other embodiments may be utilized, and structural, logical, and intellectual changes may be made without departing from the scope of the present invention. Moreover, it is to be understood that various embodiments of the invention, although different, are not necessarily mutually exclusive. For example, a particular feature, structure, or characteristic described in one embodiment may be included within other embodiments. Those skilled in the art can appreciate from the foregoing description that the techniques of the embodiments of the invention can be implemented in a variety of forms. Therefore, while the embodiments of this invention have been described in connection with particular examples thereof, the true scope of the embodiments of the invention should not be so limited since other modifications will become apparent to the skilled practitioner upon a study of the drawings, specification, and following claims.

What is claimed is:

1. An apparatus comprising:
an air mover coupled to an electronic device and positioned in relative proximity to an electronic component, wherein the air mover has an intake region, and wherein the air mover is configured such that the intake region includes a first bisection larger than a second bisection.

2. The apparatus of claim 1, further comprising:
a power connection to power the air mover module.

3. The apparatus of claim 1, further comprising:
a temperature sensor in relative proximity to the electronic component, wherein the temperature sensor is preset to at least activate the air mover.

4. The apparatus of claim 1, wherein the air mover includes a blower fan, a coaxial fan, a piezoelectric fan, or a membrane fan.

5. The apparatus of claim 1, further comprising:
a configuration module coupled to the air mover to alter the configuration of the air mover such that the intake region is altered.

6. The apparatus of claim 1, wherein the electronic component includes a spreader or heat exchanger.

7. The apparatus of claim 6, wherein the air mover is integrated into the spreader or the heat exchanger.

8. The apparatus of claim 1, wherein air mover is coupled to the electronic component.

9. The apparatus of claim 1, wherein the electronic component is one of a memory, a hard drive, a network card, a video graphics card, a motherboard, or a heat source.

10. The apparatus of claim 1, wherein the electronic device is a computing device or electronic appliance.

11. A computer system comprising:
a housing; and
an air mover coupled to an electronic device and positioned in relative proximity to an electronic component, wherein the air mover has an intake region, and wherein the air mover is configured such that the intake region includes a first bisection larger than a second bisection.

12. The computer system of claim 11, further comprising:
a power connection to power the air mover module.

13. The computer system of claim 11, further comprising:
a temperature sensor in relative proximity to the electronic component, wherein the temperature sensor is preset to at least activate the air mover.

14. The computer system of claim 11, wherein the air mover includes a blower fan, a coaxial fan, a piezoelectric fan, or a membrane fan.

15. The computer system of claim 11, further comprising:
a configuration module coupled to the air mover to alter the configuration of the air mover such that the intake region is altered.

16. The computer system of claim 11, wherein the electronic component includes a spreader or heat exchanger.

17. The computer system of claim 16, wherein the air mover is integrated into the spreader or the heat exchanger.

18. The computer system of claim 11, wherein air mover is coupled to the electronic component.

19. The computer system of claim 11, wherein the electronic component is one of a memory, a hard drive, a network card, a video graphics card, a motherboard, or a heat source.

20. The computer system of claim 11, wherein the electronic device is a computing device or electronic appliance.

21. The computer system of claim 11, wherein the air mover operates to provide air flow for the computer system.

22. A method comprising:
determining one or more configurations involving an air mover, wherein each of the one or more configurations result in an intake region-of the air mover having a first bisection larger than a second bisection; and
aligning the air mover in at least one of the one or more configurations.

23. The method of claim 22, further comprising:
operating the air mover to move air over an electronic component.

24. The method of claim 22, wherein the one or more configurations are provided by a configuration module.

25. The method of claim 22, wherein the electronic component is one of a central processing unit, a processor, a memory, a hard drive, a network card, a video graphics card, a motherboard, or a heat source.
